(19) United States
(12) Patent Application Publication
(10) Pub. No.: US 2017/0221783 A1
(43) Pub. Date: Aug. 3, 2017

(54) SELF-AWARE PRODUCTION WAFERS

(71) Applicants: Leonard TEDESCHI, San Jose, CA (US); Kartik RAMASWAMY, San Jose, CA (US)

(72) Inventors: Leonard TEDESCHI, San Jose, CA (US); Kartik RAMASWAMY, San Jose, CA (US)

(21) Appl. No.: 15/009,692

(22) Filed: Jan. 28, 2016

(51) Int. Cl. H01L 21/66

(52) U.S. Cl. CPC H01L 22/34; H01L 22/26

(57) ABSTRACT

Embodiments include a self-aware substrate and methods for utilizing a self-aware substrate. In one embodiment, a method of processing a self-aware substrate may include initiating a processing operation on the self-aware substrate. The processing operation may be any processing operation used in the fabrication of functioning devices on a production substrate. The method may further include receiving output signals from one or more sensors on the self-aware substrate. In some embodiments, the one or more sensors are formed on non-production regions of the substrate. The method may further include comparing the output signals to an endpoint criteria that is associated with one or more processing conditions. For example, the endpoint criteria may be associated with processing conditions such as film thickness. The method may further include ending the processing operation when the endpoint criteria is satisfied.

### BACKGROUND

1) Field

Embodiments relate to the field of semiconductor processing and, in particular, to devices and methods for characterizing processing on a production substrate in real time.

2) Description of Related Art

Deposition and removal rates are typically measured by processing a substrate for a given amount of time, and then measuring the amount of film deposited or removed using a film thickness measurement tool (e.g., ellipsometer). The issue with this technique is that only the end result of the process can be determined. As such, the real time changes to the film during the course of the processing cannot be determined. In some cases, the use of optical emission spectroscopy (OES) can provide some real time information about the plasma, but still lacks the ability to determine the effect that the plasma has on the surface of the substrate. Additionally, OES is not suitable for use with remote plasmas.

Additionally, in production substrates (e.g., wafers that are being processed to form a plurality of dies on a semiconductor surface), metrology is often performed to ensure that the processing was performed to proper specifications. If metrology reveals that the specifications were not met, then the layer may need to be reworked. In order to produce a high yield, metrology may need to be performed after multiple critical operations. The additional metrology and reworking reduces the throughput of each substrate and increases the overall cost of producing each device.

### SUMMARY

Embodiments include a self-aware substrate and methods for utilizing a self-aware substrate. In one embodiment, a method of processing a self-aware substrate may include initiating a processing operation on the self-aware substrate. The processing operation may be any processing operation used in the fabrication of functioning devices on a production substrate. The method may further include receiving output signals from one or more sensors on the self-aware substrate. In some embodiments, the one or more sensors are formed on non-production regions of the substrate. For example, non-production regions may be saw-streets. As such, the yield of the substrate is not decreased since the sensors only occupy regions where functioning devices cannot be located. The method may further include comparing the output signals to an endpoint criteria that is associated with one or more processing conditions. For example, the endpoint criteria may be associated with processing conditions such as film thickness. The method may further include ending the processing operation when the endpoint criteria is satisfied.

In some embodiments, the self-aware substrate may include a substrate with a plurality of sensors formed on non-production regions over a support surface of the substrate. One or more production regions may be formed on the support surface of the substrate. For example, the production regions may include die regions or display regions. According to an embodiment, each sensor is capable of producing an output signal that corresponds to a processing condition. For example, the output signals may include voltages, currents, frequencies, and/or time measurements. The processing conditions may include one or more of a film thickness, presence or absence of a particle, a mass, a substrate temperature, a chuck temperature, a surface charge, a magnetic field strength, a specific gas concentration, an electron energy distribution function (EEDF) of a plasma, or voltage direct current (VDC). Additionally, embodiments include a self-aware sensor that includes a network interface device formed on the substrate. Each of the plurality of sensors may be communicatively coupled to the network interface device by one or more vias. In one embodiment, the network interface device may be formed in a cavity in the substrate.

The above summary does not include an exhaustive list of all embodiments. It is contemplated that all systems and methods are included that can be practiced from all suitable combinations of the various embodiments summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1A is an illustration of a bottom surface of a substrate that includes electrical circuitry and a plurality of sensors, in accordance with an embodiment.

FIG. 1B is an illustration of an upper surface of the substrate showing the sensor locations in the non-production regions between die locations, in accordance with an embodiment.

FIG. 1C is an illustration showing a cross-sectional view of the substrate that includes through vias to connect sensor pads through the thickness of the substrate to the electrical circuitry on the bottom surface, in accordance with an embodiment.

FIG. 2A is an illustration showing a partial cross-sectional view of the substrate with a sensor formed on the sensor pad, in accordance with an embodiment.

FIG. 2B is an illustration showing a plurality of back-end-of-line (BEOL) layers formed over the substrate with a second sensor formed above the BEOL layers, in accordance with an embodiment.

FIG. 3 is an illustration of electronic circuitry that is mounted on the self-aware substrate, in accordance with an embodiment.

FIGS. 4A-4C are illustrations of sensors that may be included in a self-aware substrate, in accordance with an embodiment.

FIG. 5 is an illustration of a self-aware substrate that is placed in a chamber of a substrate processing tool, in accordance with an embodiment.

FIG. 6 is an illustration of a flowchart representing operations in a method for providing real time monitoring of a process, in accordance with an embodiment.

FIG. 7 is an illustration of a flowchart representing operations in a method that utilizes sensor output signals from a first processing operation to adjust a process recipe that will be used in a second processing operation, in accordance with an embodiment.

FIG. 8 illustrates a block diagram of an exemplary computer system that may be used in conjunction with a self-aware substrate, in accordance with an embodiment.

### DETAILED DESCRIPTION

Devices and methods used for monitoring a processing condition on a substrate in real time are described in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Existing techniques for verifying that a processing operations on a substrate has been properly performed are time consuming and expensive. For example, when the thickness of deposited film needs to be verified, the substrate needs to be removed from the deposition chamber and analyzed using a different tool. For example, a metrology tool, such as an ellipsometer, may be used to determine the final film thickness obtained by the deposition process.

This typical verification process has several disadvantages. First, the process verification uses more than one tool. The additional metrology tool takes up valuable space in a fabrication facility. Additionally, the use of multiple tools generates additional substrate transportation operations, and therefore increases the time needed to verify the process. Secondly, the process verification is only able to determine the thickness of the film after the process is completed. As such, if there is an error in the deposition process (e.g., the film is too thick or too thin), then the substrate may need to be reworked. The additional time to rework the substrate decreases throughput and, therefore, adds to the overall cost of the device.

Accordingly, embodiments include substrates that have sensors that are able to provide real time analysis of the processing operation. As such, embodiments eliminate the need for expensive metrology equipment and allow for real time analysis of the conditions on the substrate surface and in the processing station during the processing operations. The sensors on the substrate allow for the thickness of the film to be determined while the film is being deposited or etched. Knowing the thickness of the film during processing provides advantages that increase yield and throughput.

Whereas previous film deposition (or etching) processes utilize a process recipe that does not change during the processing operation, embodiments described herein allow for dynamic changes to the process recipe. For example, the thickness of the film at a given point during processing can be compared to the desired target thickness of the film. In a deposition process, if the film is too thin after the process recipe is supposed to have been completed, then the recipe may be adjusted in real time to increase the length of the deposition process until the desired thickness is reached. Similarly, if the desired thickness is reached before the process recipe is completed, then the process recipe may be adjusted to end early in order to avoid the need for reworking the substrate. Additionally, a subsequent processing recipe may be modified to account for the variation of the film thickness from the desired target value. For example, if a film is deposited to a thickness greater than is desired in a first process, a second process (e.g., an etching process) may be adjusted to increase the etching time.

Furthermore, embodiments provide the ability to catch manufacturing errors earlier in the manufacturing process. For example, some device layers may be susceptible to damage at high surface charges, temperatures, exposure to high strength magnetic fields, etc. However, current metrology equipment only allows inspection after a processing operation is completed, and this type of damage may not even be detectable. In contrast, embodiments described herein may include one or more sensors designed to monitor these critical parameters in order to determine if a maximum threshold is passed during the processing operation. For example, sensors that are used to monitor changes in film thickness, presence or absence of particles, mass, substrate temperature, chuck temperature, surface charge, magnetic field strength, specific gas concentration, electron energy distribution function (EEDF) of a plasma, VDC, or the like may be formed on the substrate. Additionally, sensors may be added or removed between processing operations in order to provide different sensors for different processing operations. As such, the choice of sensors may be tailored to detect only the needed information for each processing operation.

It will be understood that the self-aware substrate and methods described below could be used in any form factor or process where real time process monitoring is beneficial. More particularly, although self-aware substrates and methods are described with respect to wafer processing for the fabrication of integrated circuits, the devices and methods may also be adapted for use in other technologies, such as displays in the electronics industry and/or photovoltaic cells in the solar industry.

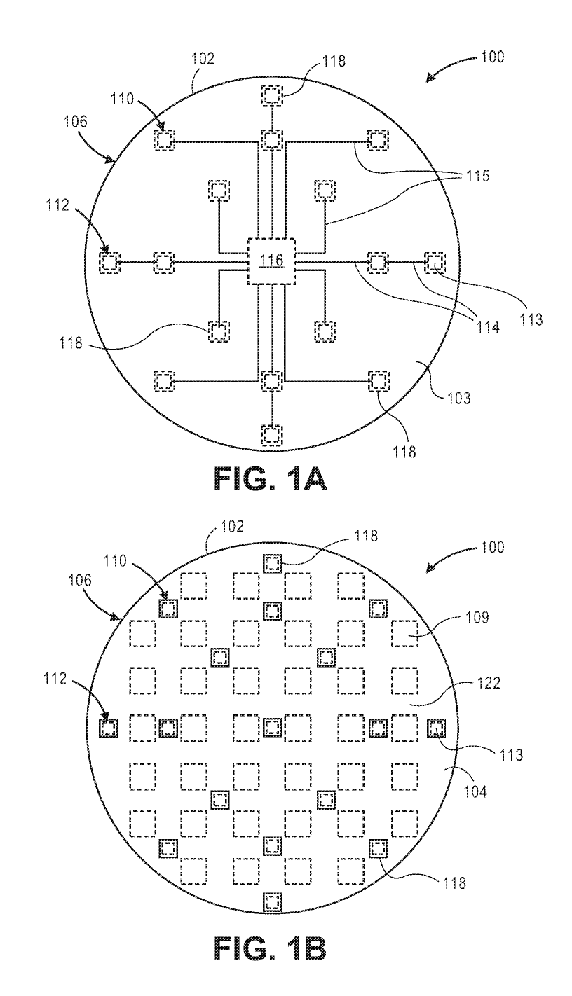

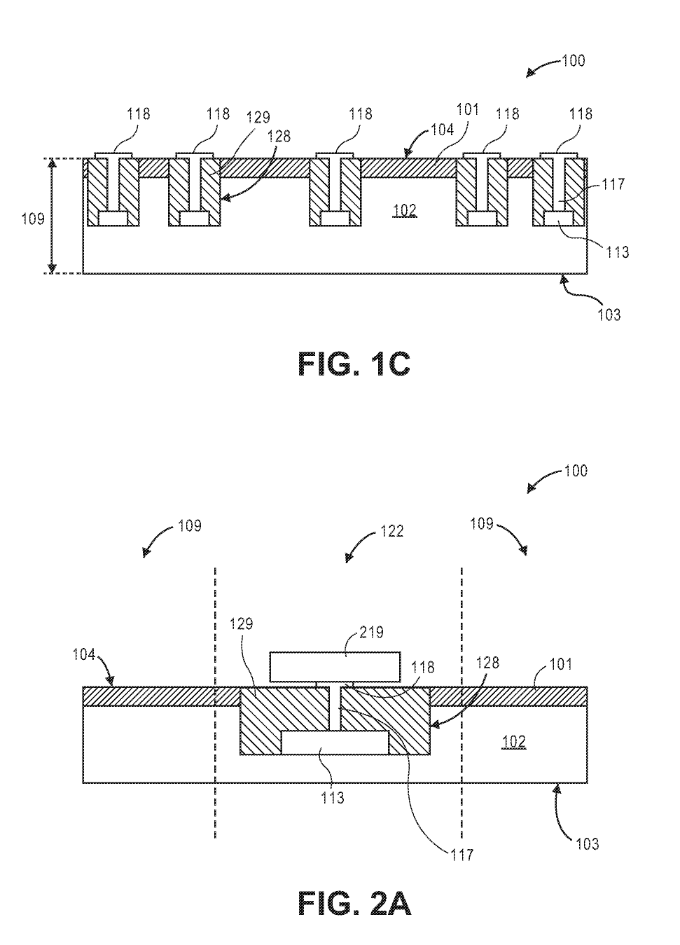

Referring now to FIG. 1A, an illustration of a backside surface 103 of a self-aware substrate 100 is shown in accordance with an embodiment. Self-aware substrate 100 may include a substrate 102 that has an overall form factor and/or a same material and shape as a semiconductor wafer. In one embodiment, substrate 102 may be at least partially composed of a semiconductor material. For example, substrate 102 may be a crystalline silicon material, a crystalline III-V semiconductor material, a silicon-on-insulator (SOI), or the like. Furthermore, substrate 102 may have a wafer form factor that is essentially disc-shaped and have a diameter 106. Substrate 102 may have a thickness 109 (shown in the cross-sectional illustration of self-aware substrate 100 illustrated in FIG. 1C). In an embodiment, the wafer form factor of substrate 102 includes diameter 106 between 95 to 455 mm (e.g., diameter 106 may nominally be 100 mm, 200 mm, 300 mm, or 450 mm). Furthermore, the wafer form factor of substrate 102 may include thickness 109 less than 1 mm (e.g., 525 μm, 775 μm, or 925 μm). Thickness 109 may also be greater than 1 mm (e.g., several millimeters up to 10 mm). Accordingly, self-aware substrate 100 may be manufactured using readily available wafer materials and typical wafer manufacturing processes and equipment, and may essentially simulate a semiconductor wafer when processed in a wafer processing tool. According to an additional embodiment, the substrate 102 may have a form factor of any type of substrate that is typically processed in a substrate processing tool. For example, glass panels that are used in display technologies (e.g., thin-film-transistor (TFT) based displays) may also be used as the substrate 102.

Self-aware substrate 100 may include one or more regions of electrical circuitry 113 formed on the substrate 102. The electrical circuitry 113 of self-aware substrate 100 may be communicatively coupled to one or more sensor pads 118 formed on a support surface 104 of substrate 102. The electrical circuitry 113 are illustrated with a dashed line to indicate that the electrical circuitry 113 may not formed on the backside surface 103 of the substrate 102. For example, the electrical circuitry 113 may be embedded in the substrate 102, as will be described in greated detail below. According to an embodiment, the electrical circuitry 113 may be electrically coupled to the sensor pads 118 by vias.

In the illustrated embodiment, each sensor pad 118 is paired with electrical circuitry 113. According to additional embodiments, more than one sensor pad 118 may be paired with each region of electrical circuitry 113. Additionally, embodiments may include an electronic circuitry hub 116. The electronic circuitry hub 116 may be communicatively coupled to each of the individual regions of electrical circuitry 113 with wired or wireless connections. For example, an electrical trace 114 embedded in the substrate 102 may connect one or more regions of electrical circuitry 113 with the electronic circuitry hub 116 in series, or one or more regions of electrical circuitry 113 may be connected with the electronic circuitry hub 116 in parallel by respective electrical traces 115. Thus, electrical connections may be made between sensor pads 118 and/or sensor pads 118 may be connected to electronic circuitry hub 116, using electrical traces, electrical leads, vias, and other known types of electrical connectors.

Referring now to FIG. 1B, an illustration of the support surface 104 of the self-aware substrate 100 is shown in accordance with an embodiment. As illustrated, one or more sensor pads 118 may be fabricated on support surface 104 at predetermined locations. In an embodiment, a plurality of sensor pads 118 (e.g., tens to millions), may be built or placed over support surface 104. Each sensor pad 118 may have a known location. For example, a first sensor pad 118 may be located at a first location 110, and a second sensor pad 118 may be located at a second location 112. Second location 112 may have a known position relative to first location 110, or relative to some other reference point on self-aware substrate 100.

Sensor pads 118 may be distributed across support surface 104 randomly or arranged in a predetermined pattern. When a random distribution is used, the absolute or relative locations of each of the sensor pad 118 may still be predetermined and known. In an embodiment, predetermined patterns used for the sensor pads 118 may include, a grid pattern, a concentric circle pattern, a spiral pattern, etc. For example, sensor pads 118 shown in FIG. 1B are distributed across support surface 104 along non-production regions 122. In some semiconductor fabrication processes, non-production regions 122 may be regions of the substrate 102 where production regions (e.g., die regions, display regions, etc.) 109 are not located. In the fabrication of integrated circuitry dies (e.g., logic, memory, or the like) the non-production regions 122 may be referred to as saw-streets or scribe lines. The non-production regions 122 provide a region where a dicing blade or a scoring blade may be used to singulate the individual die formed on the production regions 109 from the substrate after processing is completed. Accordingly, forming the sensor pads 118 along the non-production regions 122 does not occupy valuable real estate that could otherwise be used to form functioning devices. Therefore, embodiments that include forming sensor pads 118 along the non-production regions 122 do not decrease the yield of a substrate.

In an embodiment, the sensor pads 118 are arranged to provide process monitoring information at locations that are predicted to have the greatest degree variation in the processing conditions during a processing operation. For example, the temperature of the substrate 102 or exposure to the plasma may vary across the surface of the substrate. Accordingly, some embodiments may include sensor pads 118 that are not uniformly distributed across the support surface 104. For example, the outer perimeter of a substrate 102 typically undergoes greater process variation than the center of the substrate 102. Therefore, the outer region may have more sensor pads 118 than a center zone of the substrate 102.

Referring now to FIG. 1C, a cross-sectional illustration of a self-aware substrate 100 is shown according to an embodiment. As described above, a plurality of sensor pads 118 may be distributed across the support surface 104. In an embodiment, each region of electrical circuitry 113 may be embedded in the substrate 102 below a sensor pad 118. For example, a cavity 128 may be formed into the substrate 102. The electrical circuitry 113 may then be formed in the cavity 128. In the illustrated embodiment, the electrical circuitry 113 is shown as extending up from the bottom surface of the cavity 128. For example, the electrical circuitry 113 may be a die that is mounted in the cavity 128. However, embodiments are not limited to such configurations. For example, the electrical circuitry 113 may be fabricated directly into the substrate 102 (e.g., when the substrate is a semiconductor substrate). A cap layer 129 may be formed in the cavity 128 in order to isolate the electrical circuitry 113 from processing conditions during the fabrication of devices on the substrate 102. In an embodiment the top surface of cap layer 129 may be substantially coplanar with a top surface of the substrate 102. Furthermore, it is to be appreciated that references to a “support surface” of the substrate may also include a top surface of the cap layer 129. As such, in some embodiments, the sensor pads 118 are formed over the top surface of the cap layer 129. In order to provide an electrical connection from the sensor pads 118 to the electrical circuitry 113, a via 117 may be formed through the cap layer 129. The cap layer 129 may be any material that can be deposited over the substrate 102. For example, the cap layer 129 may be an oxide, a nitride, a polysilicon, an epitaxially grown semiconductor material, or the like.

FIG. 1C also illustrates a device layer 101 of the substrate 102. In an embodiment, the device layer 101 is the portion of the substrate 102 in which functioning semiconducting devices (e.g., transistors, diodes, etc.) may be fabricated. The device layer 101 may be the same material as the substrate 102. Alternatively, the device layer may be a different material than the substrate 102. For example, the substrate 102 may include a silicon semiconducting material and one or more buffer layers and the device layer 101 may be a III-V semiconducting material.

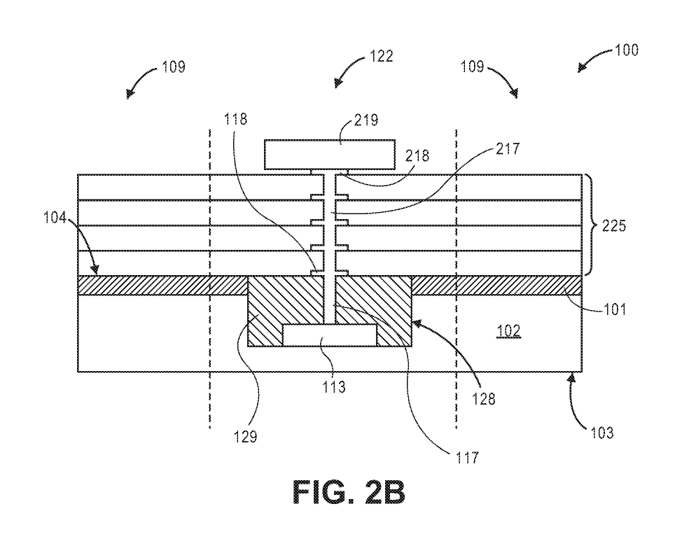

Referring now to FIG. 2A, a cross-sectional illustration of a portion of a self-aware substrate 100 is shown in accordance with an embodiment. In FIG. 2A the dashed lines illustrate the boundary between the production regions 109 and the non-production regions 122. In the non-production region 122, a sensor 219 is formed on the sensor pad 118. The sensor pad 118 communicatively couples the sensor 219 to the electrical circuitry 113 formed in the cavity 128 with via 117. According to an embodiment, the sensor 219 may be fabricated on the sensor pad 118 or the sensor may be mounted on the pad 118. While the sensor 219 and the sensor pad 118 are illustrated as being formed above the support surface 104, embodiments are not limited to such configurations. For example, the sensor 219 may be fabricated into the substrate 102 or the device layer 101 of the substrate 102.

The sensor 219 may be any sensor suitable for monitoring a given processing operation to which the substrate will be exposed. For example, the sensors 219 may include sensors for measuring changes in film thickness, presence or absence of particles, mass, substrate temperature, chuck temperature, surface charge, magnetic field strength, specific gas concentration, EEDF of a plasma, VDC, or the like. Specific examples of how these sensors 219 may be implemented are disclosed in greater detail below.

Referring now to FIG. 2B, a cross-sectional illustration of a portion of a self-aware substrate 100 after several processing operations is shown in accordance with an embodiment. The embodiment illustrated in FIG. 2B demonstrates that a sensor 219 may be used even after additional layers are formed over the support surface 104. For example, interconnect layers 225 in the back-end-of-line BEOL stack may be formed above the support surface 104. In order to continue using sensors 219 to monitor processing operations at different levels, a new sensor pad 218 may be connected to the previous pad 118 with additional vias 217 formed through the additional layers 225. In the illustrated embodiments, a new sensor pad 218 and via 217 are formed for each layer (and the sensor 219 formed on each layer is removed after the sensor 219 is no longer needed). As such a sensor 219 that is different from sensor 219 formed on sensor pad 118 may be formed or mounted to the exposed sensor pad 218. However, if a sensor is not need during the production of a new layer, then the pad may be omitted. When a new sensor 219 is eventually needed, a via 217 may then be made through multiple layers until a previous sensor pad 118/218 is reached.

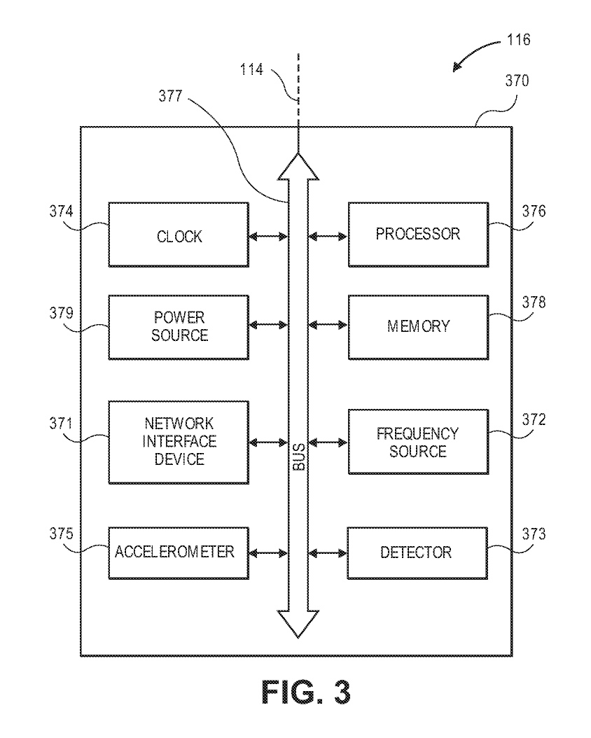

Referring now to FIG. 3, an illustration of a block diagram of electronic circuitry hub 116 of a self-aware substrate 100 is illustrated in accordance with an embodiment. While reference in FIG. 3 is made to the electronic circuitry hub 116, it is to be appreciated that one or more of the components of electronic circuitry hub 116 may be included at each region of electrical circuitry 113 distributed across the substrate 102. Additionally, in some embodiments, the electronic circuitry hub 116 may be omitted, and one or more of the components described in FIG. 3 may be provided in each region of electrical circuitry 113. Electronic circuitry hub 116 of self-aware substrate 100 may be enclosed or supported in a housing 370. Housing 370 and/or electronic components of electronic circuitry hub 116 may be mounted on substrate 102 (e.g., in a cavity 128). Electronic circuitry hub 116 may nonetheless be placed in electrical connection with sensors 219 through one or more electrical traces 114/115 and vias 117.

In an embodiment, electronic circuitry hub 116 of self-aware substrate 100 may include a clock 374 mounted on substrate 102. The clock 374 may be an electronic circuit having an electronic oscillator (e.g., a quartz crystal) to output an electrical signal having a precise frequency, as is known in the art. Thus, clock 374 may be configured to output a time value corresponding to the electrical signal. The time value may be an absolute time value independent of other operations, or the time value may be synchronized to other clocks in substrate processing tools (described in greater detail below). For example, clock 374 may be synchronized to a system clock of substrate processing tools, such that the time value output by clock 374 corresponds to a system time value and/or system operations that are output or controlled by the system clock. Clock 374 may be configured to initiate the output of the time value when a particular process operation occurs. For example, electronic circuitry hub 116 may include an accelerometer 375 that triggers clock 374 to begin outputting the time value when self-aware substrate 100 ceases movement. Thus, the time value may provide information about when self-aware substrate 100 is loaded into a particular processing station of substrate processing tool.

In an embodiment, electronic circuitry hub 116 of self-aware substrate 100 may include a processor 376 mounted on substrate 102. Processor 376 may be operably coupled (e.g., electrically connected by bus 377 and/or traces 114/115) to one or more sensors 219 and to clock 374. Processor 376 represents one or more general-purpose processing devices such as a microprocessor, central processing unit, or the like. More particularly, processor 376 may be a complex instruction set computing (CISC) microprocessor, reduced instruction set computing (RISC) microprocessor, very long instruction word (VLIW) microprocessor, a processor implementing other instruction sets, or processors implementing a combination of instruction sets. Processor 376 may also be one or more special-purpose processing devices such as an application specific integrated circuit (ASIC), a field programmable gate array (FPGA), a digital signal processor (DSP), network processor, or the like.

Processor 376 is configured to execute processing logic for performing the operations described herein. For example, processor 376 may be configured to transmit and/or record the predetermined location of a sensor 219, the time value output by clock 374, and an output signal from the sensor 219. Accordingly, processor 376 may be configured to transmit and/or record real time processing conditions that occur on the substrate 102 during a processing operation.

In some embodiments, electronic circuitry hub 116 may include a network interface device 371. The network interface may communicate data through the use of modulated electromagnetic radiation through a non-solid medium. The network interface device 371 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, etc. Processor 376 may communicate with the network interface device 371 via bus 377 or other electrical connection. Thus, processor 376 may be operably coupled to network interface device to transmit the output signals from the sensors 219 and the time value output by clock 374 to an external device.

According to an embodiment, the network interface device 371 is communicatively coupled to the sensors 219 so that an output signal from each of the sensors 219 may be sent to the network interface device 371 without being processed by a processor or any other component first. The network interface device 371 may then transmit the output signals to a computing device that is external to the self-aware substrate 100. As such, embodiments may include a self-aware substrate 100 that has electronic circuitry hub 116 that includes a power source 379 and a network interface device 371, since the output signals from the sensors 219 may not need to be processed or stored locally. In such embodiments, data from the sensor output signals may be processed or recorded on an external device.

Offloading the processing and storage functions to an external device has several benefits. First, the power consumption of the device is reduced. Accordingly, a battery may not be needed since a capacitor bank, piezoelectric springs, or the like may provide sufficient power to transmit the output signals. Additionally, reducing the complexity of the electronic circuitry by removing unneeded components provides a more reliable and less expensive device.

Transmitting the output signals from sensors 219 in real time also allows for processing operations to be precisely controlled. Instead of relying on a process recipe to determine the processing parameters, the sensors may provide nearly simultaneous feedback of what is happening on the substrate. For example, if a processing operation is needed to deposit a film of a certain thickness, the process may continue until the output signals indicate that the thickness of the film has reached the desired level. A more detailed explanation of such a process is described in greater detail below.

Electronic circuitry hub 116 of self-aware substrate 100 may optionally include a memory 378 mounted on substrate 102. Memory 378 may include one or more of a main memory (e.g., read-only memory (ROM), flash memory, dynamic random access memory (DRAM) such as synchronous DRAM (SDRAM) or Rambus DRAM (RDRAM), etc.), a static memory (e.g., flash memory, static random access memory (SRAM), etc.), or a secondary memory (e.g., a data storage device). Processor 376 may communicate with memory 378 via bus 377 or other electrical connection. Thus, processor 376 may be operably coupled to memory 378 to record the output signals from the sensors 219 and the time value output by clock 374 in the memory 378.

Electronic circuitry hub 116 of self-aware substrate 100 may include a power source 379 mounted on substrate 102. Power source 379 may include a battery, a capacitor bank, or another known power supply. Power source 379 may be electrically connected to one or more of the components of self-aware substrate 100 through bus 377, to power the connected components. For example, power source 379 may be electrically connected to one or more of the sensors 219, clock 374, processor 376, or memory 378, to power the one or more of the sensors 219, clock 374, processor 376, or memory 378.

Electronic circuitry hub 116 of self-aware substrate 100 may include additional components electrically connected to the components of self-aware substrate 100 described above. More particularly, electronic circuitry hub 116 may include a frequency source 372 (e.g., a broad frequency source) or a detector 373. Frequency source 372 and/or detector 373 may be mounted on substrate 102. Frequency source 372 and detector 373 may have particular application in relation to specific embodiments of sensors 219 of self-aware substrate 100. Thus, further description of frequency source 372 and detector 373 is reserved for the corresponding sensor discussion below.

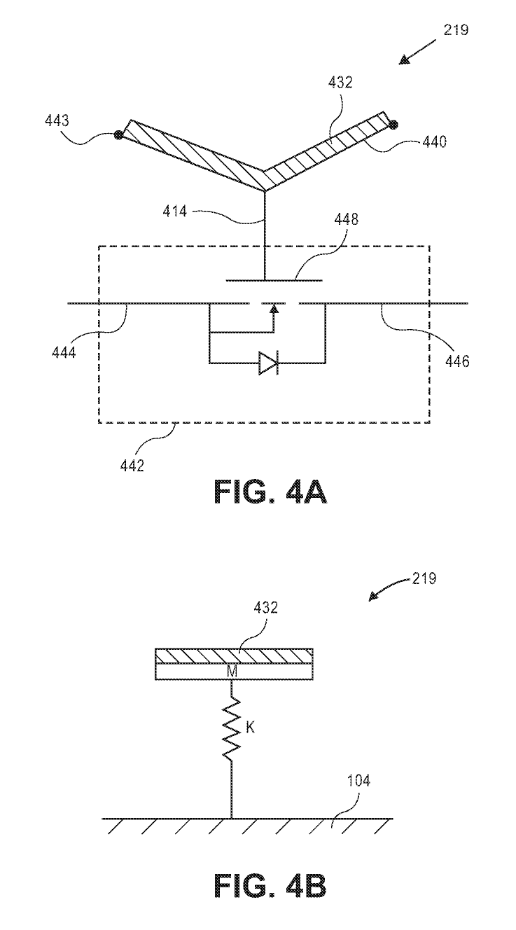

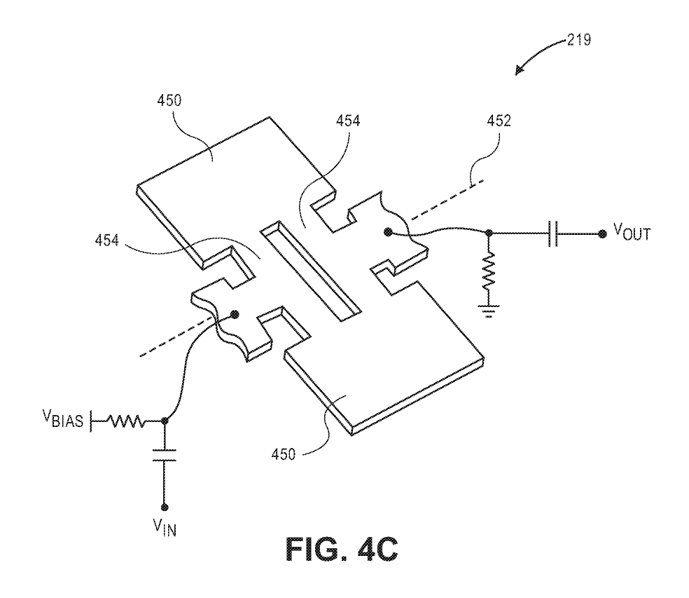

Referring now to FIG. 4A, a schematic illustration of a transistor sensor type of sensor 219 of a self-aware substrate 100 is illustrated in accordance with an embodiment. In an embodiment, one or more sensors 219 of self-aware substrate 100 include a transistor sensor 219. Transistor sensor 219 may include one or more transistors (e.g., a metal oxide semiconductor field effect transistor (MOSFET) 442. MOSFET 442 may include a source 444, a drain 446, and a gate 448. Transistor sensor 219 may also include a collector 440. Collector 440 may be formed to have a surface on which a film 432 may be deposited. In an embodiment, the film 432 may be a film that will change in thickness during a processing operation (e.g., the film thickness will increase during a deposition process, and be reduced during an etching process). Accordingly, embodiments include a collector 440 that is a material that is etch resistant to the etching process used to reduce the thickness of the film 432.

In an embodiment, collector 440 is electrically connected to MOSFET 442. For example, collector 440 may be electrically connected to gate 448 of MOSFET 442 through electrical trace 414. Collector 440 may be physically separated from MOSFET 442, however, the subcomponents may be electrically connected with each other. Thus, MOSFET 442 may be configured to detect an increase or decrease in the thickness of the film 432 on collector 440 even when collector 440 is located at a predetermined location spaced apart from MOSFET 442.

In an embodiment, the collector 440 may include a profile defined by an outer rim 443. A shape of outer rim 443 when viewed in a downward direction may be circular, rectangular, or any other shape. Furthermore, collector 440 may be flat (i.e., collector 440 may have an essentially planar upper surface) or collector 440 may have a conical upper surface as shown in FIG. 4A. In an embodiment, collector 440 is not a separate structure from MOSFET 442, but instead, is incorporated into MOSFET 442. For example, collector 440 may be a collection area on gate 448 of MOSFET 442.

In an embodiment, an output signal of transistor sensor 219 may be a threshold voltage of MOSFET 442 as measured across gate 448. The threshold voltage may correspond directly to the thickness of film 432 on collector 440. For example, the threshold voltage may have a first value when no film 432 is on the collector 440 and the threshold voltage may have a second value (different than the first value) when a film 432 is on collector 440. Thus, the threshold voltage of MOSFET 442 may change in response to the thickness of the film 432 on collector 440. Processor 376 may be configured to detect a change in the threshold voltage, and thus, self-aware substrate 100 can note the change in the thickness of the film 432 at the location of transistor sensor 219. Additional embodiments may include transmitting the output signal (i.e., the threshold voltage) to an external computing device with the network interface device 371.

Referring now to FIG. 4B, a schematic illustration of a resonator type of sensor 219 of a self-aware substrate 100 is illustrated in accordance with an embodiment. In an embodiment, one or more sensors 219 of self-aware substrate 100 include a resonator type sensor 219. A resonator sensor 219 may be a suitable resonant mass sensor, such as a Quartz Crystal Microbalance (QCM), Surface Acoustic Wave (SAW), or Film Bulk Acoustic Resonators (FBAR), which are all known to quantify the cumulative mass of a film 432 deposited on their surfaces. A description of the complexity and variety of resonators is not described here in favor of a simplified description for the purpose of brevity and ease of understanding. The resonator sensor 219 may be formed at predetermined locations across support surface 104 of substrate 102. Each resonator sensor 219 may have a characteristic frequency (e.g., a resonant frequency) as is known in the art. For example, without going into great detail, resonator sensor 219 may be represented by a simple mass-spring system as is shown in FIG. 4B. The characteristic frequency of resonator sensor 219 may be inversely proportional to a mass M of the resonator sensor 219. For example, the characteristic frequency may be proportional to sqrt(k/M) of the micro-resonator system, where ‘M’ corresponds to mass M and ‘k’ corresponds to a proportionality constant of the resonator sensor 219. Thus, it will be recognized that the characteristic frequency shifts when a thickness of the film 432 on the resonator sensor 219 changes. Accordingly, the thickness of the film 432 may be monitored during the deposition or etching of the film 432.

Referring now to FIG. 4C, a schematic illustration of a resonator type of sensor 219 of a self-aware substrate 100 is illustrated in accordance with an embodiment. One exemplary type of resonator sensor 219 that may be used is a microelectromechanical system (MEMS) resonant mass sensor, such as a thermally actuated high-frequency single crystalline silicon resonator. Such resonator type sensors 219 may be fabricated on the support surface 104 as individual devices or arrays using single mask processes. A resonator sensor 219 may include two pads 450 on either side of a plane of symmetry 452. A fluctuating electrical current may be passed between the two pads 450 to cause an alternating current (AC) ohmic loss component in the current path. In an embodiment, most of the ohmic loss occurs in thin pillars 454 that interconnect the pads 450. Thin pillars 454 may be centrally located and extend between the pads 450 in a direction orthogonal to plane of symmetry 452. Fluctuating temperature generated in pillars 454 may cause an AC force, and an alternating thermal stress in pillars 454, to actuate resonator sensor 219 in an in-plane resonant mode. In the in-plane resonant mode, pads 450 having mass ‘M’ vibrate in opposite directions. Thus, at resonance, resonator sensor 219 includes a characteristic frequency of the vibrating pads 450, and a resistance of pillars 454 is modulated by an alternating mechanical stress due to a piezoresistive effect. Accordingly, there is a detectable small signal motional current in resonator sensor 219 corresponding to the characteristic frequency.

To detect a shift in the characteristic frequency of resonator sensor 219, frequency source 372 and detector 373 may be incorporated in electronic circuitry hub 116 of self-aware substrate 100. Frequency source 372 may be a broad frequency source that is used to excite resonator sensor 219. Detector 373 may monitor the characteristic frequency of resonator sensor 219, and detect changes of the characteristic frequency. For example, detector 373 may output a signal corresponding to the characteristic frequency (e.g., an output voltage or current) to processor 376. Processor 376 may be configured to receive the output voltage and recognize the change of the characteristic frequency. Thus, when a change in the output voltage and/or when the characteristic frequency of resonator sensor 219 changes, self-aware substrate 100 can note the change as a change in the thickness of the film 432. The time and location of change in the thickness of the film 432 may also be recorded as well in order to provide process monitoring of the change in the thickness of the film 432 at a particular location during the entire course of the processing operation. For example, as mass M of resonator sensor 219 increases (e.g., as the thickness of the film 432 increases) the characteristic frequency will shift down, allowing self-aware substrate 100 to capture a history of film thickness increase. Alternatively, when a processor and memory are not included in the self-aware substrate 100, the output signal may be transmitted to an external computing device by the network interface device 371 to provide real time process monitoring of the processing operation.

While exemplary transistor sensors and resonant sensors are provided herein, it is to be appreciated that any sensor may be used to monitor different processing conditions on a substrate or in a processing station during a processing operation. Any sensor that is able to generate an output signal (e.g., an output voltage, an output current, a frequency, a time measurement, or the like) that corresponds to a processing condition (e.g., changes in film thickness, presence or absence of particles, mass, substrate temperature, chuck temperature, surface charge, magnetic field strength, specific gas concentration, electron energy distribution function (EEDF) of a plasma, VDC, or the like) may be used as a sensor 219, in accordance with various embodiments.

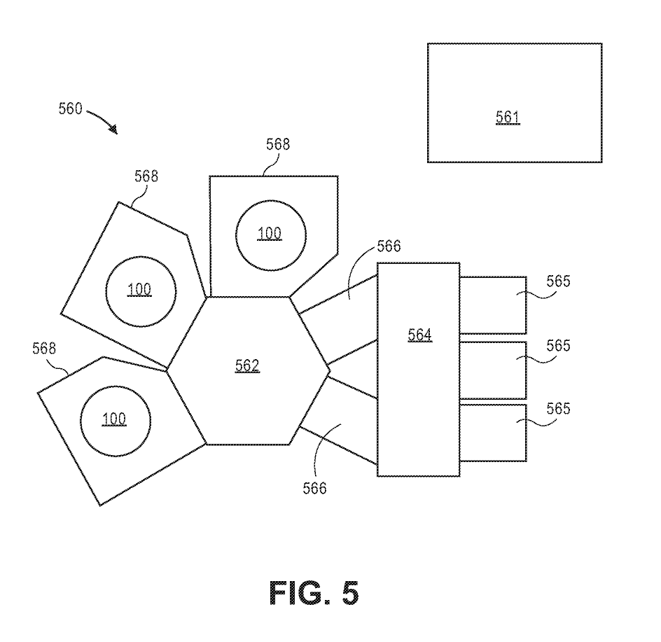

According to an embodiment, a self-aware substrate 100 may be used in conjunction with any substrate processing station. A plan view illustration of one exemplary substrate processing station (e.g., a substrate processing tool 560) is illustrated in FIG. 5 in accordance with an embodiment. A substrate processing tool 560 may include a buffer chamber 562 physically connected to a factory interface 564 by one or more load locks 566. The factory interface 564 may be able to accommodate one or more front opening unified pods (FOUPs) 565 used to transport substrates between tools in a fabrication facility. In embodiments where the self-aware substrates 100 have a form factor similar to those of production substrates, the same equipment (e.g., FOUPs, substrate transfer robots (not shown), etc.) may be used to transport the self-aware substrates 100 within a fabrication facility.

One or more processing chambers 568 may be physically connected to buffer chamber 562 directly or by one or more respective load locks (not shown). Buffer chamber 562 may essentially act as an intermediate volume, larger than respective volumes of processing chambers 568, that remains at a low pressure, albeit at a pressure higher than the process pressures within processing chambers 568. Thus, a substrate (e.g., a self-aware substrate) may be moved between chambers of substrate processing tool 560 under vacuum (or near vacuum) conditions during the manufacture of semiconductor devices. This movement may be enabled by various devices included in the substrate processing tool 560 (e.g., robotic arms, shuttles, etc.) that are not shown in order to not overly complicate the illustration.

Various manufacturing operations may be performed in processing chambers 568. For example, at least one of processing chambers 568 may be a plasma etch chamber, a deposition chamber, a chamber of a lithography tool, or any other semiconductor process tool chamber. As such, processing chamber 568 may be used to perform manufacturing processes under vacuum conditions, atmospheric conditions, or any other pressure regime. Each sensor 219 of self-aware substrate 100 may be configured to sense a change in a given processing condition (e.g., changes in film thickness, presence or absence of particles, mass, substrate temperature, chuck temperature, surface charge, magnetic field strength, specific gas concentration, electron energy distribution function (EEDF) of a plasma, VDC, or the like) during processing operations implemented by the various processing chambers 568.

Substrate processing tool 560 may be coupled to an external computer or server 561. The external computer 561 may be used to provide recipes for processing operations to be performed on substrates, monitor the flow of substrates throughout the facility, and generally to provide an automated fabrication process. The substrate processing tool 560 may be wired or wirelessly coupled to the external computer 561. In an embodiment, the computer 561 may also be incorporated into the processing tool 560. In an embodiment, the computer 561 may receive output signals from each of the chambers 568 that correspond to chamber processes, such as voltages, gas flow rates, pressure settings, or the like. Additionally, the computer 561 may be wirelessly coupled to the self-aware substrate 100 by the network interface device 371 of the self-aware substrate 100.

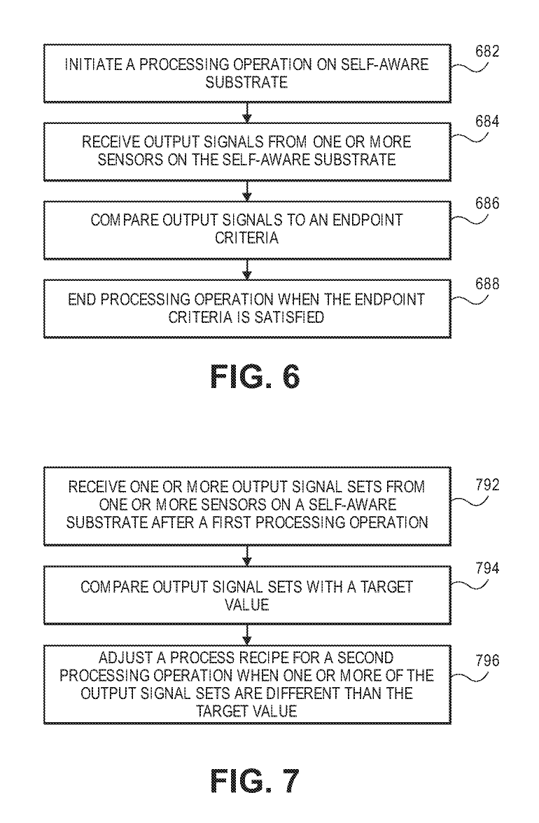

As such, embodiments allow for real time process conditions to be transmitted during the processing operations to the external computer 561. The external computer 561 may be configured to process the output signals from the sensors 219 on the self-aware substrate in order to determine if a desired endpoint (e.g., film thickness) has been reached. Relying on real-time data from the surface of the substrate allows for more precise control of the processing operations than is possible when relying solely on process recipes. Furthermore, since the thickness of a film is known when the processing operation is completed, additional metrology operations may be omitted. Methods for using a self-aware substrate 100 in various ways are described in greater detail below with respect to FIGS. 6 and 7.

Referring now to FIG. 6, an illustration of a flowchart representing operations in a method for monitoring and controlling a substrate processing operation with a self-aware substrate 100 in a substrate processing station is illustrated in accordance with an embodiment. At operation 682, an external computer 561 may initiate a substrate processing operation of a self-aware substrate 100 in a substrate processing station (e.g., substrate processing tool 560). Self-aware substrate 100 may have the structure and components described above (e.g., a plurality of sensors 219 formed in non-production regions 122 between production regions 109, and a network interface for transmitting output signals obtained from the one or more sensors 219). Each of the sensors 219 may be configured to produce an output signal that corresponds to a process condition on the substrate surface. In the exemplary embodiment described herein, the process condition that is being monitored is film thickness in a deposition process. However, it is to be appreciated that other processing conditions (e.g., presence or absence of particles, mass, substrate temperature, chuck temperature, surface charge, magnetic field strength, specific gas concentration, electron energy distribution function (EEDF) of a plasma, VDC, or the like) may be monitored instead of, or in addition to, film thickness.

In an embodiment, the substrate processing operation may be implemented by the substrate processing tool 560 in accordance with a process recipe. For example, the substrate processing tool 560 may receive a process recipe from the external computer 561. The process recipe may be stored in a memory accessible to an external computer 561. In an embodiment, the processing recipe may be for a deposition process, an etching process, an exposure process, or any other processing operation used in the fabrication of devices on substrates.

In an embodiment, the process recipe may include an endpoint criteria that is associated with the processing condition that is being monitored by the one or more sensors 219 on the substrate 102. For example, in a film deposition or etching operation, the endpoint criteria may be a desired film thickness. In some embodiments, the endpoint criteria may necessitate that the film thickness reported by all sensors 219 be at least a predetermined target value. Additional embodiments may include an endpoint criteria that necessitates a threshold percentage of the sensors 219 reach the predetermined target value (e.g., at least 95% of the sensors have reached or exceeded the predetermined target value). Other embodiments may include an endpoint criteria where all of the sensors 219 reach at least a threshold percentage of the predetermined target value (e.g., all of the sensors report at least 95% of the predetermined target value). In yet another embodiment, the endpoint criteria may correspond to more than one type of processing condition (e.g., film thickness and temperature may both be used to produce endpoint criteria).

In some embodiments, at operation 682, a clock 374 on the self-aware substrate 100 may be activated and synchronized with a clock associated with the processing tool 560. For example, the clock 374 may be activated by an accelerometer 375 on the self-aware substrate 100 detecting the deceleration to zero movement. Synchronizing the clock 374 on the self-aware substrate 100 with a clock associated with the processing tool 560 allows for data from the processing tool to be overlayed with data from the self-aware substrate 100.

At operation 684, output signals from the one or more sensors 219 formed on the substrate 102 may be received by the external computer 561. The output signals from the sensors 219 may be transmitted to the external computer 561 by the network interface device 371. Accordingly, real time analysis of the change in process conditions may be obtained. In an embodiment, the output signals may correspond to a processing condition on the substrate 102 that is related to the endpoint criteria. In the specific example of a film deposition operation, the output signals may correspond with film thickness. Other embodiments may include output signals that may correspond to the presence or absence of particles, mass, substrate temperature, chuck temperature, surface charge, magnetic field strength, specific gas concentration, electron energy distribution function (EEDF) of a plasma, VDC, or the like. In an embodiment, the output signals may be an output voltage, an output current, a frequency, a time measurement, or the like. According to an embodiment, multiple sensor types may be used in order to provide output signals for more than one processing condition.

At operation 686, the external computer 561 may compare the output signals from the one or more sensors 219 to the endpoint criteria. In some embodiments, the external computer 561 may compare the output signals to the endpoint criteria by first converting each output signal to a value for the processing condition. For example, a voltage may be converted into a value for a film thickness. In an embodiment, the conversion may be made with a look-up table that pairs an output signal value with a processing condition value. The external computer 561 may then check the converted output signals against the endpoint criteria to determine if the endpoint criteria is satisfied.

At operation 688, the external computer 561 may end the processing operation when the endpoint criteria is satisfied. For example, the external computer 561 may deliver instructions to the processing tool 560 to instruct the processing tool 560 to cease the processing operation. As such, the processing operation may not depend on a processing recipe in order to provide an endpoint for the processing. Instead, embodiments allow for the endpoint to be dependent on the actual conditions on the substrate surface.

Such real time monitoring of the processing operation allows for more precise control of the processing operation and allows for greater repeatability between substrates. For example, the processing conditions in a chamber 568 may change after repeated use (e.g., due to residual deposition along chamber sidewalls, uneven wear of components, etc.) that may result in changes in deposition or etch rates. Reliance on a single process recipe may not be able to account for these changes and result in inconsistencies between substrates. Instead, embodiments provide immediate adjustments to the processing operation that are capable of accounting for inconsistent processing conditions in a chamber.

According to an additional embodiment, a process for using the self-aware substrate 100 may include adjusting a future processing recipe based on the observed conditions on a substrate. A flowchart representing operations in such a process is illustrated in FIG. 7.

At operation 792, an output signal set from one or more sensors 219 on a self-aware substrate 100 may be received by an external computer during or after the self-aware substrate 100 is processed with a first processing operation in a processing station (e.g., processing tool 560. The first processing operation implemented in the processing tool 560 may be executed in accordance with a process recipe or with a processing operation substantially similar to the one described with respect to FIG. 6. In an embodiment, the output signals from the sensors 219 may be transmitted to the external computer 561 by the network interface device 371. Accordingly, the final result of a processing operation may be obtained without the need for additional metrology. In an embodiment, the output signals may correspond to a processing condition on the substrate 102. In the specific example of a film deposition operation, the output signals may correspond with film thickness. Other embodiments may include output signals that may correspond to the presence or absence of particles, mass, substrate temperature, chuck temperature, surface charge, magnetic field strength, specific gas concentration, electron energy distribution function (EEDF) of a plasma, VDC, or the like. In an embodiment, the output signals may be an output voltage, an output current, or the like. According to an embodiment, multiple sensor types may be used in order to provide output signal sets for more than one processing condition.

Furthermore, while the term “output signal set” is used, it is to be appreciated that embodiments may use any number of output signals received from a sensor 219. For example, in a film thickness sensor 219, the final output signal may be used, whereas all of the output signals from a substrate temperature sensor 219 may be used. With regard to film thickness, the final value may be the critical for modifying future processing operations, whereas the maximum temperature reached or the cumulative thermal energy acquired by the substrate during the processing operation may be critical for modifying future processing operations (e.g., to account for the amount of the thermal budget spent during the processing operation).

At operation 794, the external computer 561 may compare the output signal sets with one or more target values. The one or more target values may be associated with a desired processing outcome from the first processing operation. For example, a target value for a deposition or etching operation may be a film thickness value. Additional target values may be associated with any other output signal set that is obtained by the external computer. For example, a thermal budget maximum may be used as a target value when substrate temperature output data is obtained, or a residual charge maximum may be used as a target value when surface charge output data is obtained. Embodiments may also include target values that are associated with a uniformity profile (e.g., uniform deposition of a film across the substrate 102). Additionally, the target value may be associate with a uniformity between one or more substrates 102 (e.g., uniform characteristics between substrates within a lot, or substrates within one or more lots). In another embodiment, the target value may be associated with process uniformity between one or more processing stations, either within a single processing tool or between processing stations in multiple processing tools.

In some embodiments, the external computer 561 may compare the output signal sets to the target values by first converting each output signal to a value for the processing condition. For example, a voltage may be converted into a value for a film thickness. The external computer 561 may then check the converted output signal sets against the one or more target values to determine if future processing operations need to be modified.

Referring now to operation 796, the external computer 561 may adjust a process recipe for a second processing operation when one or more of the output signal sets are different than the target value. In the case where the first processing operation is a deposition processing operation, if the output signal set indicates that the target value was exceeded, then a second processing operation (e.g., an etching operation) may be modified to increase the etch rate or length of the etching process. Similarly, if a target value is a maximum use of the thermal budget, and the first processing operation exceeded the maximum thermal budget, a second processing operation may be modified to reduce the thermal budget use. For example, the second process may be modified to run at a lower temperature and at a longer duration.

Accordingly, the self-aware substrate 100 may be utilized in a manner that improves yield by allowing for customized processing recipes to be generated as a result of data obtained from the substrate during each processing operation. Additionally, the real-time adjustment to processing recipes allows for expensive and time consuming rework of a substrate to be avoided.

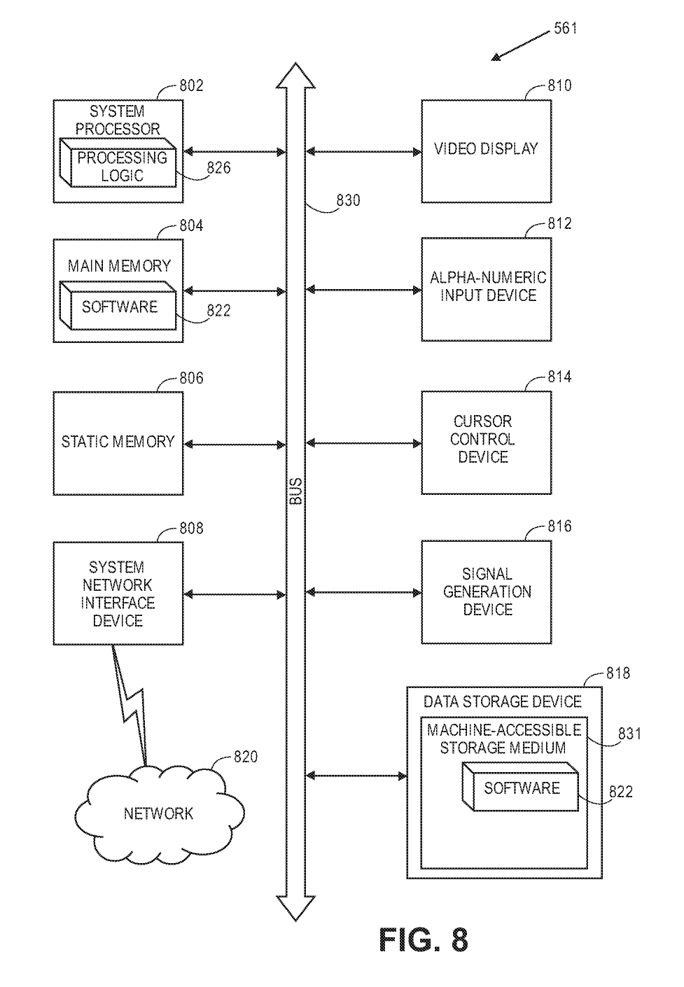

Referring now to FIG. 8, a block diagram of an exemplary computer system 561 of a substrate processing tool 560 is illustrated in accordance with an embodiment. One or more components of the illustrated computer system 561 may be used in electronic circuitry hub 116 of self-aware substrate 100. Furthermore, substrate processing tool 560 may incorporate computer system 561. In an embodiment, computer system 561 is coupled to and controls robots, load locks, processing chambers, and other components of substrate processing tool 560. Computer system 561 may also provide a system log file for substrate processing tool 560 as discussed above. Computer system 561 may also receive and analyze output signals obtained from self-aware substrate 100. That is, the computer system 561 may be implemented in substrate processing tool 560 to control process operations of a wafer manufacturing process, generate a log file to record times and actions related to the process, and compare the log file of data recorded by self-aware substrate 100 in order to determine how changes to processing conditions alter the conditions on the surface of the self-aware substrate 100.

Computer system 561 may be connected (e.g., networked) to other machines in a Local Area Network (LAN), an intranet, an extranet, or the Internet. Computer system 561 may operate in the capacity of a server or a client machine in a client-server network environment, or as a peer machine in a peer-to-peer (or distributed) network environment. Computer system 561 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 561, the term “machine” shall also be taken to include any collection of machines (e.g., computers) that individually or jointly execute a set (or multiple sets) of instructions to perform any one or more of the methodologies described herein.

Computer system 561 may include a computer program product, or software 822, having a non-transitory machine-readable medium having stored thereon instructions, which may be used to program computer system 561 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 561 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic for performing the operations described herein.

The computer system 561 may further include a system network interface device 808 for communicating with other devices or machines, e.g., self-aware substrate 100. The computer system 561 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 561, the main memory 804 and the system processor 802 also constituting machine-readable storage media. The software 822 may further be transmitted or received over a network 820 via the system network interface device 808.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of processing a self-aware substrate, comprising:
initiating a processing operation on the self-aware substrate;
receiving output signals from one or more sensors on the self-aware substrate;
comparing the output signals to an endpoint criteria that is associated with one or more processing conditions; and
ending the processing operation when the endpoint criteria is satisfied.

2. The method of claim 1, wherein the endpoint criteria includes a predetermined target value.

3. The method of claim 2, wherein the endpoint criteria is satisfied when at least one sensor provides an output signal that equals the predetermined target value.

4. The method of claim 2, wherein the endpoint criteria is satisfied when all sensors provide an output signal that equals or exceeds the predetermined target value.

5. The method of claim 2, wherein the endpoint criteria includes two or more predetermined target values, each associated with a different processing condition.

6. The method of claim 1, further comprising:
synchronizing a clock on the self-aware substrate with a clock associated with the processing tool; and
overlaying processing tool sensor data with the sensor outputs.

7. The method of claim 1, wherein the self-aware substrate comprises:
a plurality of sensors formed on non-production regions over a support surface of the substrate, wherein the substrate includes one or more production regions, and wherein each sensor is capable of producing an output signal that corresponds to a processing condition; and
a network interface device formed on the substrate, wherein each of the plurality of sensors is communicatively coupled to the network interface device.

8. A method for analyzing a processing operation, comprising:
receiving one or more output signal sets from one or more sensors on a self-aware substrate during or after a first processing operation; and
comparing the one or more output signal sets with a target value, wherein the target value is associated with a processing condition.

9. The method of claim 8, further comprising:
adjusting a process recipe for a second processing operation when one or more of the output signal sets are different than the target value.

10. The method of claim 9, wherein the target value is a film thickness.

11. The method of claim 10, wherein the process recipe of the second processing operation is adjusted by modifying an etch rate and/or modifying a duration of the second processing operation.

12. The method of claim 9, wherein the target value is a thermal budget maximum.

13. The method of claim 12, wherein the process recipe of the second processing operation is adjusted to decrease a temperature of the second processing operation.

14. The method of claim 8, wherein the output signal sets are compared to two or more target values.

15. A self-aware substrate, comprising:
a substrate;
a plurality of sensors formed on non-production regions over a support surface of the substrate, wherein the substrate includes one or more production regions, and wherein each sensor is capable of producing an output signal that corresponds to a processing condition; and
a network interface device formed on the substrate, wherein each of the plurality of sensors is communicatively coupled to the network interface device by one or more vias.

16. The self-aware substrate of claim 15, wherein the network interface device is formed in a cavity in the substrate, and wherein the cavity is filled with a cap layer.

17. The self-aware substrate of claim 15, further comprising:
one or more layers formed over the support surface of the substrate, wherein the plurality of sensors are formed on an uppermost layer of the one or more layers.

18. The self-aware substrate of claim 15, wherein the output signals are voltages, currents, frequencies, or time measurements, and wherein the processing conditions include one or more of a film thickness, presence or absence of a particle, a mass, a substrate temperature, a chuck temperature, a surface charge, a magnetic field strength, a specific gas concentration, an electron energy distribution function of a plasma, or VDC.

19. The self-aware substrate of claim 18, wherein at least two different types of sensors are formed over the substrate.

20. The self-aware substrate of claim 15, wherein at least one of the sensors is a resonator sensor or a transistor sensor.
